(19) United States
(12) Patent Application Publication
(10) Pub. No.: US 2004/0227538 A1
(43) Pub. Date: Nov. 18, 2004

(54) Test apparatus for evaluating voltage regulators

(76) Inventor: Philip M. Harris, San Diego, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/846,382

(22) Filed: May 13, 2004

Related U.S. Application Data
(60) Provisional application No. 60/470,388, filed on May 13, 2003.

(51) Int. Cl. G01R 31/02

(52) U.S. Cl. 324/763

(57) ABSTRACT

A test apparatus for testing and evaluating voltage regulator assemblies to obtain both static and dynamic output characteristics includes a printed circuit board 32, power delivery pad contacts 34 and dynamic test circuitry 36. The power delivery pad contacts 34 are configured to make electrical contact with the output compliant contacts 33 of a transition connector assembly 17 or directly to the contacts of a VRM. In addition, the dynamic test circuitry 36 can be located in the same or nearly the same location as the device that will receive the power from the VRM 16 when in actual use.

### RELATED APPLICATIONS

The application claims the benefit of U.S. Provisional Application Serial No. 60/470,388 filed May 13, 2003, titled “Test Apparatus for Evaluating Voltage Regulators” which is hereby incorporated by reference.

### BACKGROUND OF THE INVENTION

### FIELD OF THE INVENTION

This invention relates to methods for testing and evaluating voltage regulator assemblies to obtain both static and dynamic output characteristics.

Microprocessors and other high performance devices require very low impedance interconnection systems for delivery of high current at high current slew-rates from a voltage regulator. Due to the nature of this high performance delivery system the evaluation of the voltage regulator assembly is often complicated. Thus, it is important to accurately test the voltage regulator in a manner as similar as possible to the manner in which it is ultimately to be used.

### BRIEF SUMMARY OF INVENTION

The present invention is directed to methods and apparatus for testing and evaluating voltage regulator assemblies. In one aspect of the invention the apparatus includes a printed circuit board having contact pads arranged to form electrical connections with contacts on a voltage regulations circuit board. Dynamic test circuitry which includes a function generator coupled to a dynamic load circuit which is located on the printed circuit board. The dynamic load is coupled to selected ones of the contact pads and is located on the printed circuit board.

In another aspect, the dynamic load comprises a gate driver coupled to the function generator with the output of the gate driver coupled to a gate of a MOSFET. A drain of the transistor is coupled to selected ones of the contact pads while the source of the transistor is coupled to selected other ones of the contact pads.

Another aspect of the invention relates to a method of utilizing the testing apparatus which includes coupling a VRM to the testing apparatus. Operating power is then provided to the voltage regulator module. The testing apparatus transmits instructions to control the operation of the voltage regulator module. The output of the voltage regulator module is monitored throughout the testing. The dynamic load presented to the voltage regulator module is then buried to emulate various operating conditions.

Other aspects of the invention will become apparent to those of ordinary skill in the art upon a review of the following detailed description in connection with the appended drawings.

### BRIEF DESCRIPTION OF THE DRAWINGS

FIG. 1 is an exploded block diagram of a test setup in which a voltage regulator module (VRM) is coupled to a test apparatus for electrically evaluating the VRM.

FIG. 2 is a block diagram and partial schematic diagram of selected elements from FIG. 1.

FIG. 3 is an isometric view of the lower test assembly.

FIG. 4 is block diagram of the test set up.

FIG. 5 is a flow chart of a test procedure.

### DETAILED DESCRIPTION OF THE EMBODIMENTS

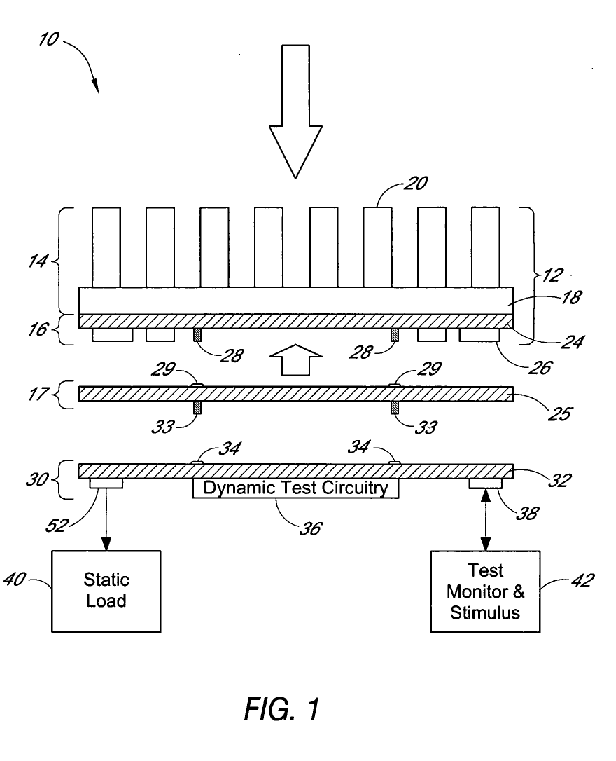

FIG. 1 is a functional block diagram of the test setup 10 for evaluating and testing a voltage regulator module (“VRM”) 16. The test assembly includes an upper assembly 12 comprising a heatsink assembly 14 and the VRM 16. A transition connector assembly 17 and lower test assembly 30 are also included. The VRM 16 is the target assembly which is being tested.

The heatsink assembly 12 comprises a base and fins 20 for coupling heat output of the VRM 16 to air or other external heat absorbing mediums. A thermal interface (not shown) facilitates efficient transfer of heat from the VRM 16 to the heatsink assembly 12. The heatsink assembly can also include a fan (not shown). The base 18 is configured to make thermal contact with the VRM 16. Other types of arrangements for dissipating the heat generated by the VRM 16 can also be used including air cooling without a finned heat since assembly.

VRM 16 can comprise a printed circuit board 24, power conversion components 26 and output delivery contacts 28 for providing power, ground and information signals such as voltage identification (programs or instructs the VRM to provide a specific voltage output), CBout (indicates when the device is in a crow bar state), power good which indicates that the power output by the device is within specification and enable (allows an outside controller to turn the VRM on or off). The output delivery contacts can be compliant. In one embodiment the VRM is configured to provide power to a device located directly below it.

The transition connector assembly 17 comprises a printed circuit board 25, power delivery pads 29 and output compliant contacts 33. In one embodiment the output compliant contacts 33 are lands which are soldered to power delivery pad contact 34 on the lower test assembly 30. The power delivery pads are configured to make electrical contact with the output delivery contacts 28 of the VRM and to provide an electrical path to the output compliant contacts 33. This allows for power from the VRM to be delivered from the VRM above the connector assembly 17, rather then, for example, using an edge connector.

Lower test assembly 30 comprises a printed circuit board 32, power delivery pad contacts 34 and dynamic test circuitry 36. The power delivery pad contacts 34 are configured to make electrical contact with the output compliant contacts 33 of the transition connector assembly 17. In addition, the dynamic test circuitry 36 can be located in the same or nearly the same location as the device that will receive the power from the VRM 16 when in actual use. The close physical and electrical proximity of the dynamic test circuitry 36 to the power delivery pad contacts 34 allows for more accurate testing and measurement. For example, a VRM such as depicted in FIG. 1 is configured to provide power to a processor which will be located below the VRM in approximately the same position as dynamic test circuitry 36. Such a VRM is described in published U.S. application Publication No. US2002/0196614A1 published on Dec. 26, 2002, titled “Method and Apparatus for Providing Power to a Microprocessor with Integrated Thermal and EMI Management,” which is hereby incorporated by reference.

Thus, as can be seen, power delivery from VRM 16 passes through compliant contacts 28 to power delivery pads 29, then through printed circuit board 25 to compliant contacts 33 and, finally, to power delivery contact pads 34. The short distance between the outputs of the VRM and the dynamic test circuitry allows for a very high rate of dynamic load current change. It will be understood that transition connector assembly 17 may not be needed and upper assembly 12 could be electrically engaged directly with lower assembly 30. However, transition connector assembly 17 can facilitate the evaluation of various compliant contacts and power delivery pads as well as planar geometries of these connector/pad combinations without requiring a change in either VRM assembly 16 or lower test assembly 30. In one embodiment, the transition connector assembly can be thought of as providing a translation of a contact pattern of a VRM to the contact pattern of the lower assembly 30.

An external static test load 40 is coupled to lower test assembly 30 by way of high current connectors or screws 52. An external monitor and stimulus system 42 is also coupled to the lower test assembly 30 by way of connector 38 to control the stimulus into both the lower test assembly 30 circuitry and/or the VRM under test and monitor test conditions associated with the tests. The static test load 40 and the dynamic test circuitry 36 are preferably located to reduce impedance. The short distance between those elements and the VRM allows for very high rate of dynamic change.

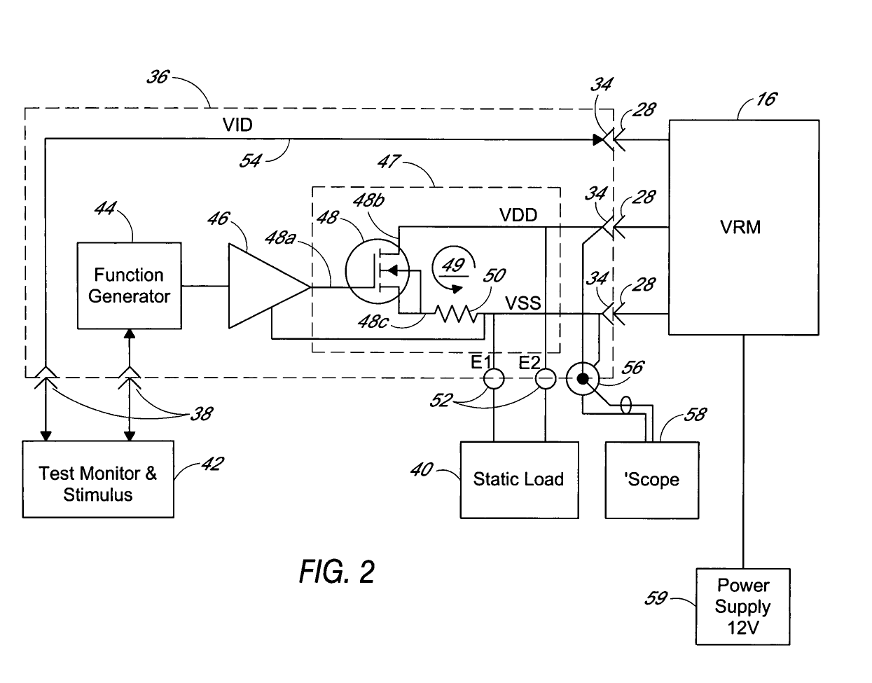

FIG. 2 is a block diagram and partial schematic diagram of the system depicted in FIG. 1, including additional elements. Note that transition connector assembly 17 has been omitted for simplicity. Dynamic test circuitry 36 includes an electronic function generator 44 which is under the control of the external monitor and stimulus system 42. Thus, explicit wave shapes from function generator 44 can be delivered to a gate driver 46 which in turn provides the input to the dynamic load circuit 47. The output of the gate driver 46 is coupled to a gate 48a of a metal-oxide-semiconductor field effect transistor (MOSFET) transistor 48. It will be recognized that the MOSFET transistor 48 may be more than one device acting in parallel to provide the necessary load conduction to the VRM 16. Power to the VRM can be supplied by an external power supply 59. In one embodiment, the MOSFET 48 is an n-channel power MOSFET. As a positive drive is applied to the gate 48a, conduction between the drain 48b and the source 48c of MOSFET 48 is enhanced. This applies a dynamically increasing load to the VRM 16 as is represented by the current loop 49. The drain 48b is coupled to one or more selected power delivery pad contacts 34 which are electrically coupled to the desired compliant contacts 28 of the VRM 16. Alternatively, the connection between the contacts 34 and the contacts 28 is achieved via the transition connector assembly 17 (not shown). The source 48c is similarly coupled to the desired compliant contacts 28 of the VRM 16 via a resistor 50. In one embodiment the electrical paths between the source 48c and one or more power delivery pad contacts 34 and the drain 48b and one or more power delivery pad contacts 34 are traces or substantial low impedance planes of the printed circuit board 32. In that way, the dynamic load can more accurately emulate a device such as a microprocessor which would receive power from the VRM.

Resistor 50 serves to set the magnitude of the dynamic test current that can be applied from VRM 16 and reduces the thermal dissipation in the MOSFET 48. The majority of the current load is typically supplied to the static load 40. Resistor 50 may also be used to determine the amount of dynamic load current being applied to VRM 16 by observing the voltage across it without the necessity for a current shunt. An oscilloscope 58 may be used to observe the voltage at the power delivery pads 34 through a connector 56. The connector 56 may be a radio frequency type connector due to the high speed of the changes in voltage to be monitored by the oscilloscope 58.

The layout construction of the lower test assembly printed circuit board 32 (FIG. 1) employs low impedance VSS and VDD planes which couple to selected ones of the power delivery pads 34. Thus, by carefully connecting oscilloscope 58 to these planes with a Kelvin voltage monitoring configuration, the oscilloscope 58 can be made to observe the output of the VRM 16 through contacts 28 and 34 without further measurement errors due to impedance losses associated with the driver circuitry. Thus, the dynamic output characteristic of both the VRM 16 and the power delivery connections 28 and 36 can be completely evaluated.

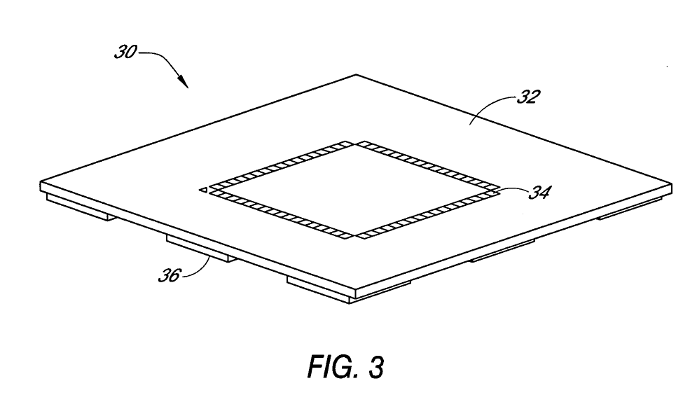

FIG. 3 is an isometric view of the lower test assembly 30. Printed circuit board 32 provides the basic interconnect for test circuitry 36. Located on the top of the board are the power delivery connection pads 34. The power delivery connection pads 34 are located on the upper surface of printed circuit board 32. The power delivery pad contacts 34 define a perimeter. In an preferred embodiment, the dynamic load circuit 47 (see FIG. 2) is located within the perimeter defined by the power delivery pad contacts 34. Though in the previous figures the dynamic load circuit 47 has been depicted on the side of the circuit board opposite to the power delivery pad contacts 34, it can, alternatively, be located on the same side. Locating the dynamic load circuit 47 within the perimeter formed by the contact pads 34 places the dynamic load circuit 47 in the same or nearly the same location as the device it is emulating, and thereby provides a more reliable test.

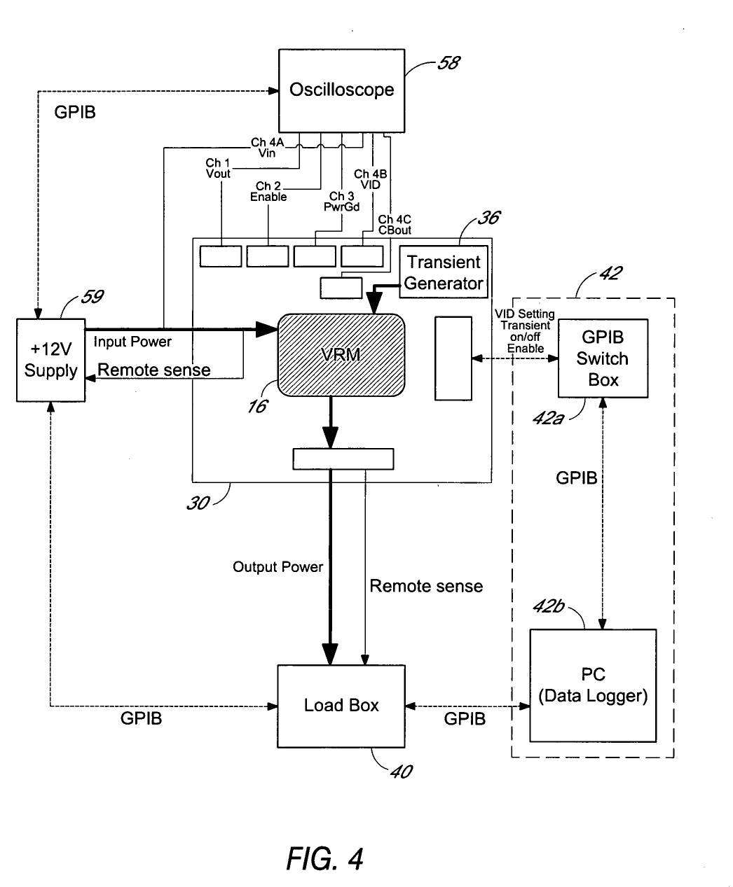

FIG. 4 is a functional block diagram of the test assembly shown in FIGS. 1 and 2. Referring to FIG. 4, the test monitor and stimulus system 42 can include a general purpose interface bus (“GPIB”) switchbox 42a which is coupled to a computer 42b via a GPIB connection. As will be apparent to those of ordinary skill in the art, alternative communication links between the elements coupled by the GPIB can also be used. The GPIB switchbox 42a is coupled to the VRM 16 and to the dynamic test circuitry 36. Via the GPIB switchbox 42a, voltage identification settings and enable signals can be sent to the VRM under test. Additionally, the electronic function generator 44 (see FIG. 2) of the dynamic test circuitry 36 receives its input via the connection to the GPIB switchbox 42a. Software or firmware on the computer 42b provides the signals to the GPIB switchbox to control the voltage identification settings, the enable setting and the control signals to the function generator. Additional signals to the VRM 16 can also be provided by the GPIB switchbox if desired.

The static load 40 is also coupled to the computer via the GPIB. In that way, the computer can control and alter the static load. As was also depicted in FIG. 2, the static load provides the static load for testing the VRM 16. The static load 40 is also coupled to a sensor at one of the contact pads 34 on the printed circuit board 32. This allows the static test load 40 to more accurately monitor the load seen at the printed circuit board 32.

The power supply 59, which provides operating power to the VRM 16, is also coupled to the GPIB. It is electrically coupled to the VRM 16 to provide operating power to the VRM being tested. A remote voltage sensor is placed at the input power supply contact on the VRM. Output from the remote voltage sensor is provided to the power supply in order to allow as accurate as possible monitoring of the power provided to the VRM 16.

The oscilloscope 58 is also coupled to the GPIB. Various inputs of the oscilloscope are connected to different contact points on the test assembly 30. Channel 4a of the oscilloscope can be used to monitor the timing of the power provided to the VRM. Channel 1 of the oscilloscope is coupled to the voltage output of the VRM. The connection is provided by, for example, Kelvin sense traces extending from a selected power delivery pad contact 34 to an appropriate connector for the oscilloscope. Channel 2 of the oscilloscope can be connected to the enable output signal of the VRM. Channel 3 can be connected to the “power good” output signal of the VRM. Channel 4b of the oscilloscope can be connected to monitor the voltage identification output by the VRM. Additionally, channel 4c can be coupled to monitor the crow bar output signal from the VRM.

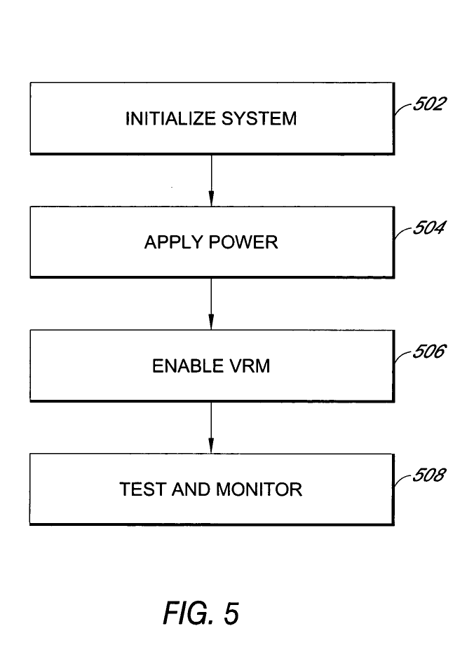

FIG. 5 is a flow chart illustrating a method of testing a VRM utilizing the apparatus described above. Software or firmware operating on the computer 42b (see FIG. 4) can be utilized to implement and control the method depicted in FIG. 5. Prior to beginning the method described herein, the VRM to be tested is connected to the test apparatus. At a step 502, the test apparatus is initialized. This can include supplying very limited current and power to the VRM while monitoring the output voltage. In addition, the voltage identification provided to the VRM via the GPIB switchbox 42a is 0. The output of the VRM is monitored to ensure that the appropriate minimum output is present and to guard against manufacturing defects causing damage to the system. The next series of steps are then utilized to test the operation of the VRM under various conditions. For example, in the step 504, the input voltage required for operation of the VRM is supplied by the power supply 59. In the step 506, instructions are sent to the VRM via the GPIB switchbox 42a including an enable signal and a voltage identification signal. At a step 508, the output of the VRM is monitored, for example using the oscilloscope 58, under various conditions. For example, the static load can be set at various levels while the dynamic test load can be run through various dynamic loads including a current step amplitude, a slew rate (current change versus time), and step duration. Each of these dynamic test loads can be run with different timings and with different static test loads. Throughout the different test combinations, the input instructions to the VRM transmitted via the GPIB switchbox, the output voltage from the VRM, and the other output signals such as enable, power good, voltage identification and crowbar-out are also monitored. During the testing process the computer 42b logs all of the generated data. In addition, also logged are the sense signals from the power supply 59 and the load box 40.

The foregoing description details certain embodiments of the invention. It would be appreciated, however, that no matter how detailed the foregoing appears the invention may be embodied by other specific forms without departing from its spirit or essential characteristics. The described embodiments are to be considered in all respects only as illustrative and not restrictive. The scope of the invention is indicated by the appended claims rather then by the foregoing description. All changes which come within the meaning and range of equivalence of the claims are to be embraced within their scope.

What is claimed is:

1. A test assembly for testing the performance of a voltage regulation circuit board configured to be mounted above the device it will power, comprising:
a printed circuit board having contact pads arranged to form electrical connections with contacts on a voltage regulation circuit board;
dynamic test circuitry comprising a function generator coupled to a dynamic load circuit on the printed circuit board, the dynamic load being coupled to selected ones of said contact pads and located on the printed circuit board.

2. The assembly of claim 1 wherein the dynamic load comprises a gate driver coupled to the function generator with the output of the gate driver coupled to a gate of a MOSFET transistor, a drain of the transistor is coupled to selected ones of the contact pads and a source of the transistor is coupled to selected other ones of the contact pads.

3. The assembly of claim 2 wherein the connections between the source of the transistor the selected ones of the contact pads is through traces of the printed circuit board.

4. The assembly of claim 2 further comprising a static load coupled across the source and the drain of the transistor.

5. The assembly of claim 4 further comprising an external monitor and stimulus system coupled to the function generator and configured to control the function generator and to provide input to a VRM.

6. A test assembly for testing the performance of a voltage regulation circuit board configured to be mounted above the device it will power, comprising:
a printed circuit board having contact pads, the contact pads defining a perimeter; and
dynamic test circuitry comprising,
a function generator,
a gate driver coupled to the function generator,
a transistor located on the printed circuit board with the perimeter defined by the contact pads, the transistor having a gate coupled to the output of the gate driver, a drain coupled to selected ones of the contact pads and a source coupled to selected other ones of the contact pads.

7. The assembly of claim 6 wherein the transistor is a metal-oxide-semiconductor field effect transistor.

8. The assembly of claim 6 wherein the connections between the source of the transistor the selected ones of the contact pads is through traces of the printed circuit board.

9. The assembly of claim 6 further comprising a transition connector assembly board having pads arranged in a first pattern to make electrical contact with contacts of a VRM and having contacts arranged in a second pattern to make electrical contact with the contact pads of the printed circuit board, with selected ones of the pads being electrically coupled to selected ones of the contacts.

10. The assembly of claim 6 further comprising a static load coupled across the source and the drain of the transistor.

11. A method of testing a voltage regulator module comprising:
forming an electrical connection between electrical contacts of a voltage regulation module and the contact pads of a test assembly comprising a printed circuit board having contact pads, the contact pads defining a perimeter, dynamic test circuitry having a function generator, a gate driver coupled to the function generator, and a transistor located on the printed circuit board with the perimeter defined by the contact pads, the transistor having a gate coupled to the output of the gate driver, a drain coupled to selected ones of the contact pads and a source coupled to selected other ones of the contact pads;
providing operating power to the voltage regulator module;
transmitting instructions to the voltage regulator module;
monitoring the output of the voltage regulator module; and
varying the load presented by the dynamic test circuitry to the voltage regulator.

12. The method of claim 11, further comprising varying a static load presented to the voltage regulator module over time.

13. The method of claim 11, wherein varying the load presented by the dynamic test circuitry to the voltage regulator comprises running the dynamic test circuitry through a current step amplitude.
